(19) United States
(12) Patent Application Publication
(10) Pub. No.: US 2014/0231886 A1
(43) Pub. Date: Aug. 21, 2014

(54) TWO-DIMENSIONAL MATERIAL STACKED FLEXIBLE PHOTOSENSOR

(71) Applicant: SAMSUNG ELECTRONICS CO., LTD., Suwon-Si (KR)

(72) Inventors: Tian-zi SHEN, Seoul (KR); Won-jong YOO, Seoul (KR); Huamin LI, Seoul (KR); Min-Sup CHOI, Seoul (KR); Jae-young CHOI, Suwon-si (KR)

(73) Assignee: SAMSUNG ELECTRONICS CO., LTD., Suwon-Si (KR)

(21) Appl. No.: 14/079,123

(22) Filed: Nov. 13, 2013

(30) Foreign Application Priority Data
Feb. 18, 2013 (KR) 10-2013-0016972

(51) Int. Cl. H01L 31/113; H01L 31/0224

(52) U.S. Cl. CPC H01L 31/1136; H01L 31/022408
USPC 257/290

(57) ABSTRACT

A flexible photosensor includes a flexible substrate, a gate on the flexible substrate, the gate including a conductive material having a planar structure, a gate insulating layer on the flexible substrate and the gate to at least cover the gate, the gate insulating layer including a non-conductive material having a planar structure, and a channel layer on the gate insulating layer, the channel layer including a semiconductor material having a planar structure.

### CROSS-REFERENCE TO RELATED APPLICATIONS

This application claims the benefit of Korean Patent Application No. 10-2013-0016972, filed on Feb. 18, 2013, in the Korean Intellectual Property Office, the disclosure of which is incorporated herein in its entirety by reference.

### BACKGROUND

1. Field

Some example embodiments relate to a flexible photosensor that is constructed by stacking a 2-dimensional (2D) material, and more particularly, to a flexible photosensor that is constructed by stacking a 2-dimensional (2D) material, is conveniently manufactured, and has improved electrical and optical characteristics.

2. Description of the Related Art

Commonly used photosensors include, for example, a photodiode that has a PN junction of a semiconductor, such as silicon, as a basic structure. However, a photosensor may be manufactured to have a transistor structure instead of a diode structure. Meanwhile, an image sensor, such as a complementary metal oxide semiconductor (CMOS) image sensor or a charge coupled device (CCD), also needs a photosensor capable of sensing light in order to capture images. Recently, an optical touch panel capable of performing the same function as that of a touch panel by sensing light instead of contact by hands or pens has been proposed. In order to manufacture such an optical touch panel, photosensors having a relatively fine size that may sense light are needed. Generally, graphite has a stacked structure of 2-dimensional (2D) graphene in a sheet-like structure, in which carbon atoms are connected to one another to form a hexagonal shape. Recently, there has been testing to inspect characteristics of graphene sheets by taking off one layer or several layers from a graphite sheet. As a result, it was discovered that graphene sheets have effective characteristics, which are distinguishable from those of conventional substances.

Since electrical conductivity of graphene is 50 to 100 times greater than that of silicon, and thus many studies on graphene as a material that may replace semiconductors, such as silicon, are in progress. Also, graphene has received attention in electronic application fields, such as displays, solar batteries, or sensors, due to its desirable electronic and photoelectronic characteristics.

Exploring graphene for flexible electronics requires solution-processable, high-capacitance gate dielectrics that can be formed at a relatively low temperature with an improved interface with the graphene films formed on plastic sheets. Although SiO₂ dielectric material-based dielectrics, or several inorganic dielectrics having a relatively high dielectric constant, such as HfO₂, Al₂O₃, and ZrO₂, have been applied to the fabrication of graphene FETs, the materials basically have 3-dimensional atomic structures, and thus their own properties are lost as atomic structures and electronic structures are destroyed when bending stress is applied thereto. Meanwhile, a material having a 2D structure such as graphene, hexagonal boron nitride (h-BN), MoS₂, NbSe₂, or BiTe₃ maintains the atomic structures and the electronic structures when bending stress is applied thereto, and thus the materials having 2D structures may maintain their intrinsic properties even when they are applied to a flexible device.

### SUMMARY

Some example embodiments provide a photosensor having improved electrical and optical characteristics.

Additional aspects will be set forth in part in the description which follows and, in part, will be apparent from the description, or may be learned by practice of the presented embodiments.

According to an example embodiment, a flexible photosensor includes a flexible substrate, a gate on the substrate, the gate including a conductive material having a planar structure, a gate insulating layer on the substrate and the gate to at least cover the gate, the gate insulating layer including a non-conductive material having a planar structure, and a channel layer on the gate insulating layer, the channel layer including a semiconductor material having a planar structure.

According to another example embodiment, the photosensor may further include an insulating layer between the substrate and the gate.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view of a structure of a flexible photosensor according to an example embodiment;

FIGS. 2(a)-(e) illustrates a stepwise stacking process for preparing the flexible photosensor;

FIGS. 3A and 3B are scanning electron microscope (SEM) images of graphite and hBN that are sequentially stacked on a polymer substrate according to an example embodiment;

FIG. 4 is a graph illustrating photoelectric currents of flexible photosensors prepared in Example 1 and Comparative Example 1 according to a gate voltage change;

FIG. 5 is a graph illustrating drain currents of the flexible photosensors prepared in Example 1 and Comparative Example 1 according to a gate voltage change; and

FIG. 6 is a graph illustrating a photoelectric current of the flexible photosensor prepared in Example 2 according to a gate voltage change.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Hereinafter, a flexible photosensor according to an example embodiment will be described in detail with reference to the accompanying drawings. Like reference numerals in the drawings denote like elements, and a size of each of the elements in the drawings may be exaggerated for clarity and convenience of description.

It will be understood that, although the terms first, second, third etc. may be used herein to describe various elements, these elements should not be limited by these terms. These terms are used to distinguish one element from another. Thus, a first element discussed below could be termed a second element without departing from the teachings of example embodiments. As used herein, the term “and/or” includes any and all combinations of one or more of the associated listed items.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A flexible photosensor according to an example embodiment includes a flexible substrate, a gate on the substrate, the gate including a conductive material having a planar structure, a gate insulating layer on the substrate and the gate to at least cover the gate, the gate insulating layer including a non-conductive material having a planar structure, and a channel layer on the gate insulating layer, the channel layer including a semiconductor material having a planar structure.

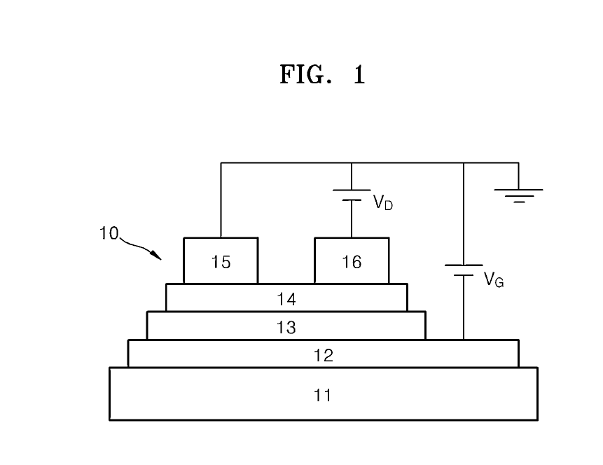

FIG. 1 is a schematic view of a structure of the photosensor according to an example embodiment. Referring to FIG. 1, a flexible photosensor 10 includes a substrate 11, a gate 12 partially disposed on the substrate 11, a gate insulating layer 13 disposed at least to cover the gate 12, and a channel layer 14 disposed on the gate insulating layer 13. Also, the flexible photosensor 10 may further include a source electrode 15 and a drain electrode 16 that are disposed so as to cover both ends of the channel layer 14.

Here, the substrate 11 is a flexible substrate which may include, for example, polymer or other flexible materials. In some embodiments, the substrate 11 may be a transparent flexible substrate. The transparent flexible substrate may be appropriately selected from known materials by one of ordinary skill in the art. Examples of the polymer may include at least one selected from polyacetate, polyethylene terephthalate, polycarbonate, polyethersulfone, polyimide, polyacrylate, polyester, polyvinyl, polyethylene, pentacene, polyetherimide, and polyethylene naphthalate, but are not limited thereto.

The gate 12 is formed of a conductive material having a planar structure and may include at least one selected from graphite, graphene, and a conductive polymer.

The conductive polymer may be at least one selected from polypyrrole, polythiophene, poly(3-alkyl thiophene), polyaniline, polyphenylene sulfide, polyfuran, polyisothianaphthene, poly(p-phenylenevinylene), poly(p-phenylene), poly(3,4-ethylenedioxythiophene), poly(ethyleneglycol)diacrylate, and 2-hydroxy-2-methylpropiophenone.

The gate insulating layer 13 is disposed on the substrate 11 and the gate 12 so as to cover the gate 12 and is formed of a non-conductive material having a planar structure. The gate insulating layer includes a 2-dimensional (2D) material with a band gap of 5 eV or higher, for example, hexagonal boron nitride (hBN).

The channel layer 14 is disposed on the gate insulating layer 13 and formed of a semiconductor material having a planar structure that is, for example, at least one selected from graphene, MoS₂, NbSe₂, and BiTe₃. For example, when photosensitive graphene is used as the channel layer 14, a transistor having a threshold voltage of variable characteristics depending on whether light is incident or not may be obtained. Thus, the transistor having such characteristics may be used as a photosensor.

Particularly, when the gate insulating layer 13 includes hBN and the channel layer 14 includes graphene, a p-n junction may be formed between the graphene and the hBN, and thus a photoelectric current may be generated.

For a flexible photosensor according to an example embodiment, every layer forming the photosensor has a 2D planar structure, and thus the whole photosensor device may be flexible. In this regard, a thickness of each layer forming the photosensor may be from about 0.3 nm to about 20 nm.

The flexible photosensor 10 according to an example embodiment may further include an insulating layer (not shown) between the substrate 11 and the gate 12. The insulating layer may be formed of a non-conductive material having a planar structure as well as the gate insulating layer 13 described above.

The source electrode 15 and the drain electrode 16 included in the flexible photosensor 10 according to an example embodiment may include graphite, conductive metal, conductive metal oxide, or conductive polymer. For example, when the flexible photosensor 10 is used in an optical touch panel, which is attached on a display panel, the source electrode 15 and the drain electrode 16 may be formed of a transparent material, such as ITO.

For example, the conductive polymer may be at least one selected from polypyrrole, polythiophene, poly(3-alkyl thiophene), polyaniline, polyphenylene sulfide, polyfuran, polyisothianaphthene, poly(p-phenylenevinylene), poly(p-phenylene), poly(3,4-ethylenedioxythiophene), poly(ethyleneglycol)diacrylate, and 2-hydroxy-2-methylpropiophenone.

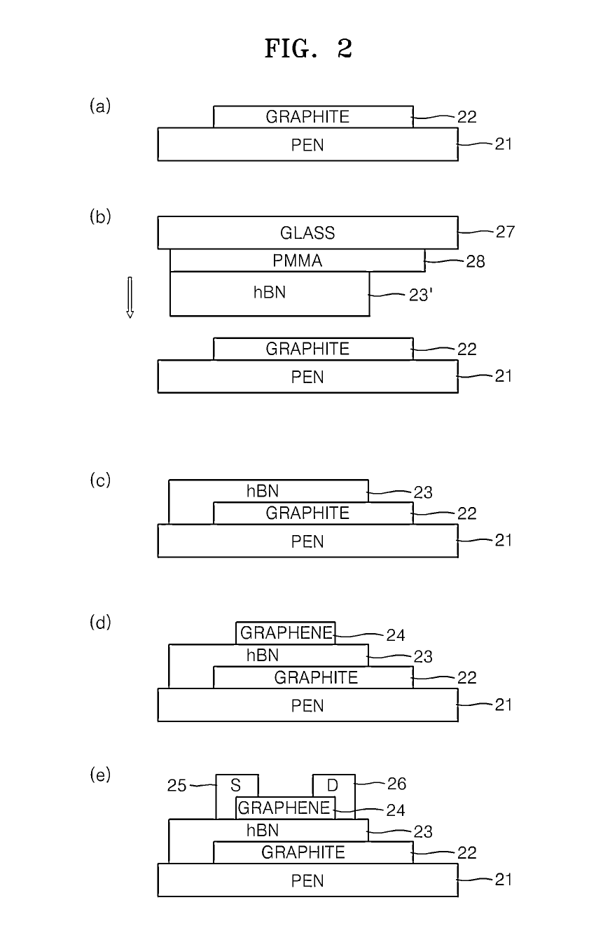

A method of preparing a flexible photosensor according to an example embodiment is not particularly limited. FIGS. 2(a)-(e) illustrates a stepwise stacking process for preparing the flexible photosensor according to an example embodiment.

As illustrated in FIG. 2(a), graphite is stacked on a polyethylenenaphthalate (PEN) substrate 21 by using a peeling method using Scotch tape to form a gate 22. However, a chemical peeling method or a chemical vapor deposition (CVD) technique may be used to prepare a photosensor with a relatively large surface area.

As illustrated in FIG. 2(c), a gate insulating layer 23 is formed on the gate 22 by using a transferring method using, for example, hBN. For example, as illustrated in FIG. 2(b), an hBN layer 23′ is formed on poly(methyl methacrylate) (PMMA) 28 on a glass substrate 27 and then transferred onto the graphite to form the gate insulating layer 23.

As illustrated in FIG. 2(d), graphene may be stacked on the gate insulating layer 23 by using a peeling method using Scotch tape to form a channel layer 24 on the gate insulating layer 23. However, a chemical peeling method or a CVD technique may be used to prepare a photosensor with a large surface area. The stacking method described herein may be applied in the same manner even when materials other than graphene or hBN are used.

As illustrated in FIG. 2(e), a source electrode 25 and a drain electrode 26 are formed on both ends of the channel layer 24. The source electrode 25 and the drain electrode 26 include a conductive material, for example, metal, metal oxide, or conductive polymer, and may be formed by using a material and a method that are available in the art. The source electrode 25 and the drain electrode 26 of metal or metal oxide may be formed of at least one selected from the group consisting of aluminum doped zinc oxide (AZO), indium tin oxide (ITO), cobalt, iron, nickel, chrome, gold, silver, copper, aluminum, platinum, tin, tungsten, ruthenium, palladium, and cadmium. The conductive polymer may be at least one selected from polypyrrole, polythiophene, poly(3-alkyl thiophene), polyaniline, polyphenylene sulfide, polyfuran, polyisothianaphthene, poly(p-phenylenevinylene), poly(p-phenylene), poly(3,4-ethylenedioxythiophene), poly(ethyleneglycol)diacrylate, and 2-hydroxy-2-methylpropiophenone.

The source electrode 25 and the drain electrode 26 may be formed by using a CVD method, a physical vapor deposition method, or a printing method. The CVD may be one of a metal organic chemical vapor deposition (MOCVD) method, an atmosphere pressure chemical vapor deposition (APCVD) method, a low pressure chemical vapor deposition (LPCVD) method, a plasma enhanced chemical vapor deposition (PECVD) method, and an atomic layer deposition (ALD).

The source electrode 25 and the drain electrode may be formed of a flowable conductive material, such as a solution, a paste, an ink, or a dispersion, including the conductive material described above.

An electrode may be formed by using a dispersion including metal particles of the conductive material dispersed in a dispersion medium, which is water or an organic solvent, by using a dispersion stabilizer that may be formed of an organic material. A method of preparing the dispersion of the metal particles may be, for example, a physical method such as a gas evaporation method, a sputtering method, or a metal vapor synthesis method or a chemical method such as a colloid method or a co-precipitation method that forms metal particles by reducing a metal ion in a liquid phase.

The source and drain electrodes 25 and 26 may be molded by using the dispersion of the metal particle. Then, the solvent may be dried, and, if necessary, the source and drain electrodes 25 and 26 may be heated up to a temperature in a range of about 100° C. to about 300° C., for example about 150° C. to about 200° C., so that the metal particle may be heat-fused to form an electrode pattern having a desired shape.

The conductive material with a low electric resistance at a surface in contact with the channel layer 24 may be used to form the source electrode 25 and the drain electrode 26. The electric resistance needs to be as low as possible in order to obtain a large mobility that corresponds to a field effective mobility when a current controlling device is manufactured.

A thickness of the source electrode 25 or drain electrode 26 prepared in such a manner is not particularly limited when a current is supplied but may be, for example, in a range of about 0.3 nm to about 300 nm. When the layer thickness is within this range, a resistance of the source electrode 25 or drain electrode 26 increases as the layer thickness decreases, and thus a voltage drop does not occur.

Although not separately shown in the drawings, a flexible photosensor including a flexible substrate, a channel layer on the substrate, the channel layer including a semiconductor material having a planar structure, a gate insulating layer on a center portion of the channel layer, the gate insulating layer including a non-conductive material having a planar structure, and a gate on the gate insulating layer, the gate including a conductive material having a planar structure may be included within the scope of the inventive concepts.

Also, the flexible photosensor may further include a source electrode and a drain electrode that are separated at each end of the gate and disposed on the channel layer. Here, the flexible substrate, the channel layer, the gate insulating layer, and the gate are stacked in a different order but correspond to the layers described above, and thus the descriptions of the layer will not be repeated here. The inventive concepts will be described in further detail with reference to the following examples, which are not intended to limit the scope of the inventive concepts.

### Example 1

First, graphite was stacked on a PEN substrate with a peeling method by using Scotch tape. PMMA was formed on a glass substrate by using a spin-coating method, and hBN with a thickness of 20 nm was formed on the PMMA by using a peeling method using Scotch tape. The hBN was transferred onto the graphite formed on the PEN substrate.

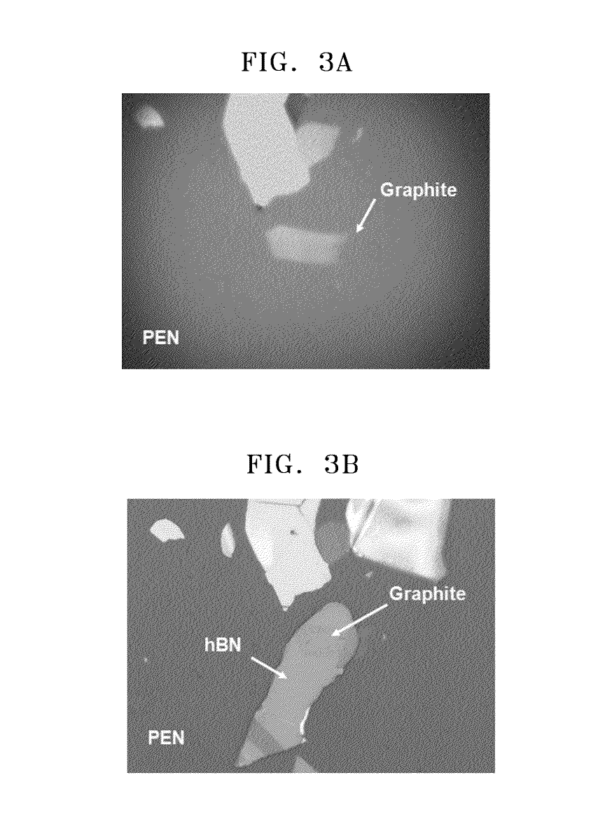

FIGS. 3A and 3B show scanning electron microscope (SEM) images in a process of stacking the hBN on the graphite. FIG. 3A shows the graphite stacked on the PEN substrate. FIG. 3B shows the hBN and the graphite stacked on the PEN substrate. As shown in FIGS. 3A and 3B, the hBN as a gate insulating layer and the graphite as a gate are stacked well on the PEN substrate.

Graphene to be used as a channel of a field effective transistor (FET) was stacked on a layer of the hBN by using a peeling method using Scotch tape.

Electrodes as a source electrode and a drain electrode were formed on a layer of the graphene with palladium by using an electron-beam vapor deposition method, and thus a flexible photosensor was obtained.

### Example 2

A photosensor was prepared in the same manner as Example 1, except that MoS₂ instead of hBN as a channel material was formed by using a peeling method using Scotch tape.

### Comparative Example 1

A photosensor was prepared in the same manner as Example 1, except that SiO₂ instead of hBN as a gate insulating layer was formed by using a chemical vapor deposition method.

A drain current according to a gate voltage change was measured to determine performance characteristics of each of the photosensors prepared in Examples 1-2 and Comparative Example 1.

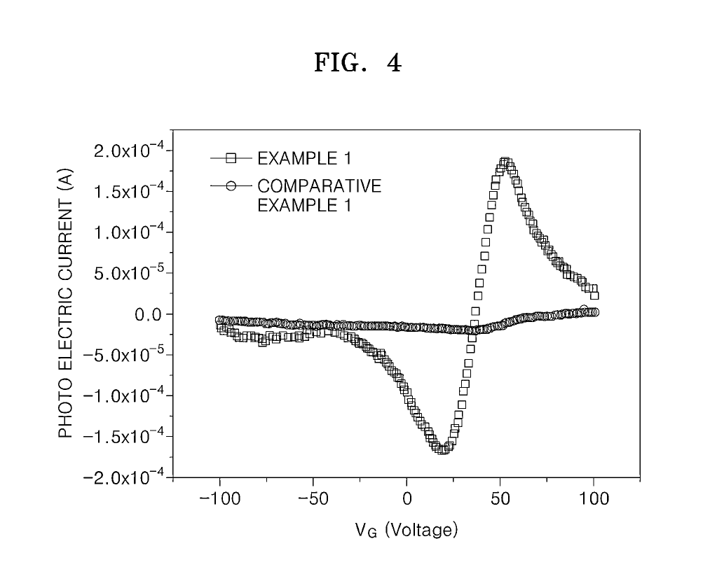

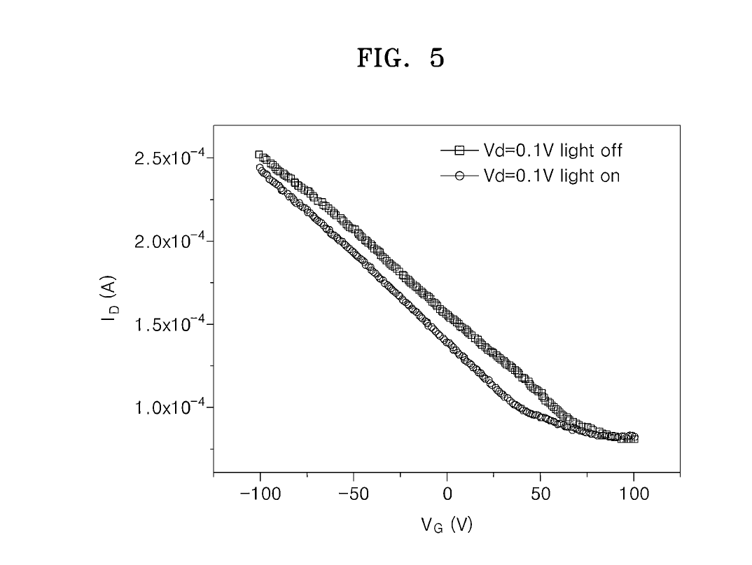

FIG. 4 is a graph illustrating photoelectric currents of the flexible photosensors prepared in Example 1 and Comparative Example 1 according to a gate voltage change. FIG. 5 is a graph illustrating drain currents of the flexible photosensors prepared in Example 1 and Comparative Example 1 according to a gate voltage change.

As shown in FIGS. 4 and 5, the flexible photosensor according to an example embodiment had improved photosensitive characteristics, while the conventional photosensor with silica as a gate insulating layer had no change with respect to light change.

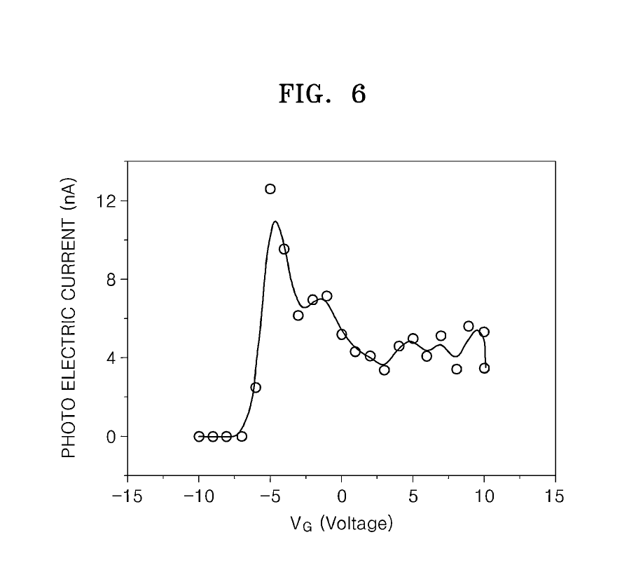

FIG. 6 is a graph illustrating a photoelectric current of the flexible photosensor prepared in Example 2 according to a gate voltage change. Referring to FIG. 6, the flexible photosensor according to an example embodiment is flexible when used in a whole device and sensitive to light.

As described above, according to the one or more of the above example embodiments, a flexible photosensor according to an example embodiment may maintain relatively high sensitivity to light, and thus the flexible photosensor may be efficiently used in an image sensor or an optical touch panel which uses fine photosensors.

It should be understood that example embodiments described herein should be considered in a descriptive sense only and not for purposes of limitation. Descriptions of features or aspects within each embodiment should typically be considered as available for other similar features or aspects in other embodiments.

What is claimed is:

1. A flexible photosensor comprising:
a flexible substrate;
a gate on the flexible substrate, the gate including a conductive material having a planar structure;
a gate insulating layer on the flexible substrate and the gate to at least cover the gate, the gate insulating layer including a non-conductive material having a planar structure; and
a channel layer on the gate insulating layer, the channel layer including a semiconductor material having a planar structure.

2. The flexible photosensor of claim 1, further comprising:
a source electrode covering one end of the channel layer; and
a drain electrode covering another end of the channel layer.

3. The flexible photosensor of claim 1, further comprising:
an insulating layer between the substrate and the gate.

4. The flexible photosensor of claim 1, wherein the flexible substrate includes at least one of polyethylenenaphthalate, polyetherimide, polyethylene terephthalate, polyethersulfone, polyimide, polyacetate, polycarbonate, polyacrylate, polyester, polyvinyl, polyethylene, and pentacene.

5. The flexible photosensor of claim 1, wherein the gate includes at least one of graphite, graphene, and conductive polymer.

6. The flexible photosensor of claim 1, wherein the gate insulating layer comprises a 2-dimensional material with a band gap of 5 eV or higher.

7. The flexible photosensor of claim 6, wherein the gate insulating layer comprises hBN.

8. The flexible photosensor of claim 1, wherein the channel layer comprises at least one of graphene, MoS₂, NbSe₂, and BiTe₃.

9. The flexible photosensor of claim 1, wherein the source and drain electrodes comprise one of graphite, a conductive metal, a conductive metal oxide, and a conductive polymer.

10. The flexible photosensor of claim 9, wherein the conductive polymer is at least one of polypyrrole, polythiophene, poly(3-alkyl thiophene), polyaniline, polyphenylene sulfide, polyfuran, polyisothianaphthene, poly(p-phenylenevinylene), poly(p-phenylene), poly(3,4-ethylenedioxythiophene), poly(ethyleneglycol)diacrylate, and 2-hydroxy-2-methylpropiophenone.

11. The flexible photosensor of claim 1, wherein the channel layer comprises graphene, and the gate insulating layer comprises hBN.

12. The flexible photosensor of claim 1, wherein a thickness of each of the flexible substrate, the gate, the gate insulating layer, and the channel layer is from about 0.3 nm to about 20 nm.

13. A flexible photosensor comprising:
a flexible substrate;
a channel layer on the flexible substrate, the channel layer including a semiconductor material having a planar structure;
a gate insulating layer on a center portion of the channel layer, the gate insulating layer including a non-conductive material having a planar structure; and
a gate on the gate insulating layer, the gate including a conductive material having a planar structure.

14. The flexible photosensor of claim 13 further comprising:
a source electrode on one end of the gate; and
a drain electrode on another end of the gate.
